(19) United States
(12) Patent Application Publication
(10) Pub. No.: US 2026/0260099 A1
(43) Pub. Date: Sep. 3, 2026

(54) Efficient compute architecture with custom latch arrays for machine learning applications

(71) Applicant: The Board of Trustees of the Leland Stanford Junior University, Stanford, CA (US)

(72) Inventors: Massimo Giordano, Mountain View, CA (US); Rohan Doshi, Menlo Park, CA (US); Boris Murmann, Honolulu, HI (US)

(21) Appl. No.: 19/165,108

(22) PCT Filed: Mar. 13, 2024
(86) PCT No.: PCT/US2024/019757

§ 371 Date: Sep. 13, 2025

Related U.S. Application Data
(60) Provisional application No. 63/451,831, filed on Mar. 13, 2023.

(51) Int. Cl. G06N 3/0464; G06N 3/045; G06N 3/063; G11C 11/419

(52) U.S. Cl. CPC G06N 3/0464; G06N 3/045; G06N 3/063; G11C 11/419

(57) ABSTRACT

Improved memory for machine learning applications is provided having remarkably low read access energy. Operation at relatively low clock rate and with a small number of cells on each bit line allows the sense amplifier for readout to be eliminated. As an example of the machine learning systems thereby enabled, we consider a multi-core system with a processing core dedicated to each of the three layers of the computation (expansion, depth-wise and projection layers). This system is configured to pipe line the computations per-pixel (in image processing), thereby significantly reducing the energy cost of each machine learning inference.

### FIELD OF THE INVENTION

This invention relates to an energy-efficient custom latch array operating as a memory and to a machine learning hardware architecture enabled by that custom latch array.

### BACKGROUND

Deploying ML (machine learning) models “at the edge” on resource-constrained devices is difficult due to limited memory and a strict power budget. Current compute architectures and ML hardware accelerators suffer from low parallelism, inefficient memory hierarchies, and dataflows that access the same data multiple times to feed compute elements. The main problems with today's computing architectures are: Memories are either dense but costly to access (high energy or latency) e.g. large SRAM (static random access memory) or have a large area but lower access energy e.g. Register File. This creates tradeoffs in the memory hierarchy—large and dense memories are used to store large amounts of parameters and activations, but accessed as few times as possible and the parameters and activations are stored in buffers (less dense, but cheaper to read) to be accessed multiple times. The ideal memory would be as dense as possible (close to the 6T bit-cell area which is the best density one can achieve in cmos logic with no read-out overheads) and be cheaper to read than a conventional standard-cell-based latch array.

Current dataflows usually use buffer activations (or weights) to amortize memory access costs and increase data reuse. This implies that the partial input or output features need to be stored in buffers until all the operations that depend on them are performed. These dependencies make it impractical to pipeline Inverted Residual and Linear Bottleneck (“bottleneck” for short) layers (because large memories would be required between the pipeline stages).

Alternative solutions, such as in-memory/analog computing architectures despite looking promising in terms of throughput and power efficiency lack flexibility—they only support a very limited number of operations (a fixed single matrix size) and don't scale to large bit precision. For conventional sram-based in-memory-computing array, which attempt to reduce data movement to reduce energy per inference, there is an unavoidable one-time cost of loading weights from main memory into the array for different input tiles if the network doesn't entirely fit in the array. This one-time cost significantly limits the performance of these approaches, as access to large memories is costly in energy.

Accordingly, it would be an advance in the art to provide a memory concept more suitable for these machine learning applications.

### SUMMARY

In this work, we consider (1) quantized and heavily pruned bottleneck-based networks enabled by (2) dense, custom latch arrays (CLAs), which lets us fit the whole network onto a tightly integrated compute-memory fabric. CLAs are small memory banks (e.g. 16 bytes) similar to SRAM but with minimal read-out circuitry, optimized for density and extremely low read energy access cost. Our CLA implementation in 28 nm achieves 60× (1.6×) lower read energy (higher density) than iso-port width SRAM macros of the same capacity made by a memory compiler and more than 5× lower energy (2× higher density) than a latch array synthesize from standard cells in the same technology). This compute-memory fabric with CLAs provide an advantage over conventional in-memory-computing based approaches because it amortizes the compute logic over several weights, allowing us to store larger networks fully in the fabric. When we can store entire networks in the array it eliminates the cost of loading the parameters of that network from outside the array.

We targeted bottleneck-based networks as they have proven extremely effective in reducing operations and parameters while providing good accuracy. The main drawback of such networks, however, is that they have expanded activations (e.g. six times larger than the inputs) as outputs of intermediate layers which require large amounts of working memory (larger memories have higher per-byte read access cost and larger silicon area). Our low-read-energy, dense CLAs and the high degree of parallelism of our dense compute fabric enable us to change the dataflow so that the inputs and outputs are only read/write once. This eliminates the need for a data buffer in the memory hierarchy, saving silicon area and memory accesses (the reduction is a polynomial factor given by the number of tiles and loops that conventional ML architecture has).

In addition, we can benefit from our new dataflow, as we can now pipeline the bottleneck layers, meaning we have three separate processors for each of the three layers in the bottlenecks (called expansion, depth-wise, and projection). The inputs are sent through the pipeline architecture one pixel at a time. Since the access cost of our CLA is so low compared to conventional SRAMS, we can access the weights more times than conventional weight-stationary dataflows with improves end-to-end energy and latency performance. In practice, for every input pixel we cycle through all the weights (of the same layer) that need to be multiplied by the input pixel, this means that we can compute the final output pixel after a single input pixel access from main memory (or buffer). Thus as soon as the output pixel is computed, we can send it immediately to the next processor in the pipeline. Note that if the dataflow is different and buffers the outputs, the pipeline would require larger intermediate memories and the pipeline would stall. This means once a pixel has gone through each of the three processors it will never be needed again so we no longer need to store it; thus we access every input exactly once from main memory.

In the case of a pipelined MobileNetV2, our architecture results in a 3.5× smaller working memory and 7× fewer main memory accesses than a conventional architecture that requires storing the intermediate activations. The tight integration between the CLA and multiplier allows for a low-energy combined weight access and multiply because tight integration allows for short wires which have a small capacitance. This tight integration is achieved through three key ways: (1) we use 1-bit-by-8-bit bit-serial multipliers with 8-bit weights and 1-bit input bits shifted in over 8 cycles, and this multiplier footprint is significantly smaller than a conventional 8-bit-by-8-bit multiplier, (2) we use custom layouts of the memory, multipliers, and digital adder tree to lower power consumption, (3) our CLAS use 6T SRAM bit-cells but do not pre-charge the bit lines or use a sense amplifier for reads which works because of an ultra-low bit-line capacitance. There is no flip-flop between the CLA and the multiplier, significantly reducing read energy. These three innovations allow one to store all parameters into the compute fabric, completely unroll the operations and avoid tiling of inputs and output.

Potential applications of this work are edge devices that perform ML inference in power/energy-constrained environments. Examples are IoT (Internet of Things) devices and high-end consumer electronics such as VR glasses, phones, and security cameras. This work could also enable running larger ML models on power-constrained devices and higher compute performance on low power/energy budget devices.

Key aspects of this work relate to memory architecture, compute cores, and pipelining. The compute cores uses CLAs which are denser and lower read energy then conventional digital latch arrays. The memory architecture, unusually, has 2-10 cells per bit line. The small number of cells per bit line simplifies readout (i.e., no sense amplifier is needed), thereby enabling read efficiencies of 11 fJ/byte or less. This also allows for unusually dense memory configurations of 8 micrometers squared per byte or less. Bit lines are short with a low capacitance. We have ratio of bit line capacitance over cell capacitance of 8 or more. The low read energy access cost allows for a dataflow that does not requires tiling inputs and outputs. The higher density of the CLA and the custom 1-bit serial multipliers enable to store all the parameters into the compute fabric thus avoiding the need to re-load parameters into the cores and stalling computation. By enabling a dataflow that does not require tiling we can pipeline the bottleneck layers. At the system level, this reduces the working memory requirements by 3× and the number of accesses by 7×.

### BRIEF DESCRIPTION OF THE DRAWINGS

FIGS. 1A-B schematically show a custom latch array according to an embodiment of the invention.

FIG. 2 schematically shows the three layers of the exemplary ML architecture.

FIG. 3 schematically shows memory access for the three layers of the exemplary ML architecture.

FIG. 4 shows several schematic block diagrams relating to the exemplary ML architecture.

FIG. 5 schematically shows how computations are done for the three layers of the exemplary ML architecture.

FIG. 6 shows inference energy for the exemplary ML architecture compared to several previous reports.

FIG. 7A schematically shows an optional pipeline bypass operating mode.

FIG. 7B schematically shows an optional column gating operating mode.

FIGS. 8A-B show a layer mapping example.

### DETAILED DESCRIPTION

Section A describes a memory concept having an unusual design. Section B is a detailed example of a machine learning system enabled by the memory concept of section A.

### A) Memory Cell Concept

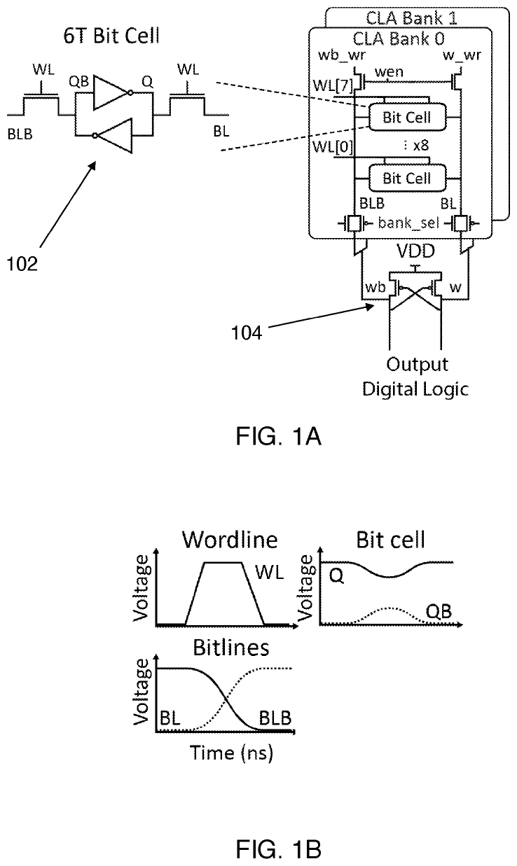

FIG. 1A schematically shows the memory concept of this work. Six-transistor cells 102 are used in a custom latch array having unconventional readout circuitry 104. Instead of the sense amplifier of conventional memories, readout circuitry 104 is merely a pair of transistors that perform a regeneration function when data is read from the memory. FIG. 1B shows schematic signal traces for operation of this memory cell. The top left shows a word line signal (no pre-charging). The top right shows signal droop being corrected by the regenerative readout (here Q and QB are complementary signals from a bit cell). In general, bit lines swing rail to rail quickly because of ultra-low bit line capacitance (lower left, here BL and BLB are complementary bit line signals).

As indicated above, this memory cell provides ultra-low readout energy, enabled mainly by the lack of a power-hungry sense amplifier in the readout circuitry. To better appreciate the present work, it will be helpful to review why a sense amplifier is conventionally regarded as essential. For large memory arrays, a large number of cells is present on each bit line, which leads to logic 1 and logic 0 being distinguished by small changes in voltage (which must therefore be amplified with the sense amplifier). Smaller memories may not suffer from this effect, but are often used in applications such as caches for main processors that require fast access (e.g., 1 GHz or greater clock rate). Here also, a sense amplifier ends up being essential, since without the amplifier, access times will typically be too slow for such requirements.

The machine learning application of this work doesn't require operation at high clock rates (100 MHz or less is suitable). Thus by having a small number of cells per bit line (e.g., 8 or less), the custom latch arrays of this work can surprisingly omit the sense amplifier, thereby greatly reducing access energy.

### B) Detailed Machine Learning Example

Medusa is a 28 nm programmable 8-bit processor that achieves state-of-the-art inference energy across a range of always-on tiny Machine Learning (tinyML) tasks. It features custom 6T-latch-based Inner Loop Memories (ILMs) optimized for tinyML that achieve a read energy of 15 fJ/Byte, and its Pipelined Pixel Streaming (PPS) architecture leverages ILMs to reduce system-level memory access energy by up to 9.5×. Medusa performs inference image-to-label, with native support for critical tinyML operations, including memory-intensive depth-wise separable convolution-based bottleneck layers. It achieves 0.83/4.6 μJ/Frame at a latency of 0.6/2.6 ms and an accuracy of 86.2/91.6% on CIFAR-10, advancing the state-of-the art in inference energy by 3.4×/4.9×. In addition, it achieves 0.23 μJ/Frame at 0.27 ms and 90.8% on Google Speech Commands and 5.0 μJ/Frame and 3.8 ms at 81.5% on Visual Wake Words.

### Introduction

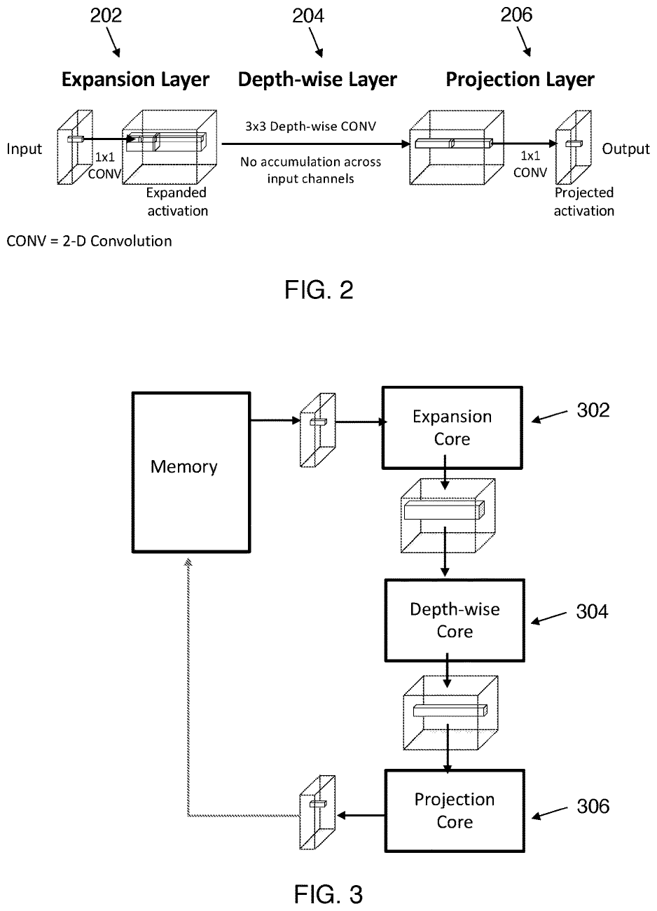

Tiny Machine Learning (tinyML) targets the deployment of deep neural networks (DNNs) on the rising number of low-cost IoT devices. Processors for tinyML face many challenges including limited on-chip memory, deployment of bottleneck layers (FIG. 2), strict power, area and energy budgets, and the energy and latency bottleneck of off-chip memory accesses. Medusa overcomes these challenges through a number of key contributions: (1) 6T-latch-based Inner Loop Memories (ILMs) optimized for tinyML with an access cost of only 15 fJ/Byte (as described above in section A); (2) a Pipelined Pixel Streaming (PPS) system architecture and dataflow (FIGS. 2-4) that leverages ILMs to reduce memory access overhead for memory-intensive bottleneck layers; (3) full-custom bit-serial multipliers and adder trees integrated with ILMs to reduce compute area and energy; and (4) an optional column gating and pipeline bypass scheme to minimize switching energy.

### Inner Loop Memories

ILMs leverage the low frequency requirements for tinyML (<100 MHz) to achieve a read access energy of 15 fJ/Byte. Each ILM is composed of 6T latch-based banks with 8 words per bit line. The bit line is designed to have a capacitance of less than 3 fF including layout parasitics, allowing the bit-cell to directly drive the subsequent logic, and thus requiring no pre-charge operation or power-hungry sense amplifier like a standard SRAM. A minimum-size 2T cross-coupled PMOS circuit (i.e., 104 on FIG. 1A) shared across the banks restores the weak logic “1”. The implemented ILMs achieve a 51× lower read energy and 2.2× higher density than a foundry SRAM with a comparable bank size that is readout-area dominated due to the limited number of words. They also achieve a 6× lower read energy and occupy 3× less area than comparable synthesized latch-based memories.

### Low-energy Digital MAC Circuitry

We used a circuit implementation for the Processing Elements containing a 16B ILM along with a 1b×8b bit-serial multiplier. The complementary ILM output signals enable the use of a 3T Transmission Gate (TG) AND gate-based multiplier. The smaller footprint of a bit-serial multiplier compared to a bit-parallel one allows for more integrated memory and loop unrolling in the same area. The full-custom adder is built as a tree of Ripple Carry Adders (RCAs) using custom 16T TG-based full adder cells. The adder tree consumes 60 fJ/8b-Op over the 8-cycle computation. The Bit-Serial Accumulator takes each partial sum at the output of the adder tree and performs a shift-add operation into a 20b accumulation register over 8 cycles.

### PPS Architecture

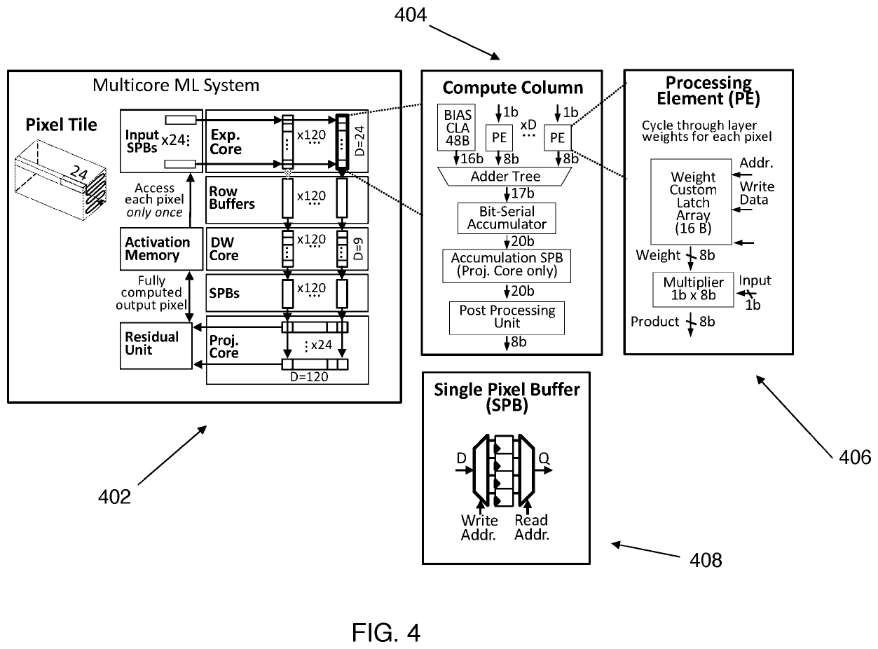

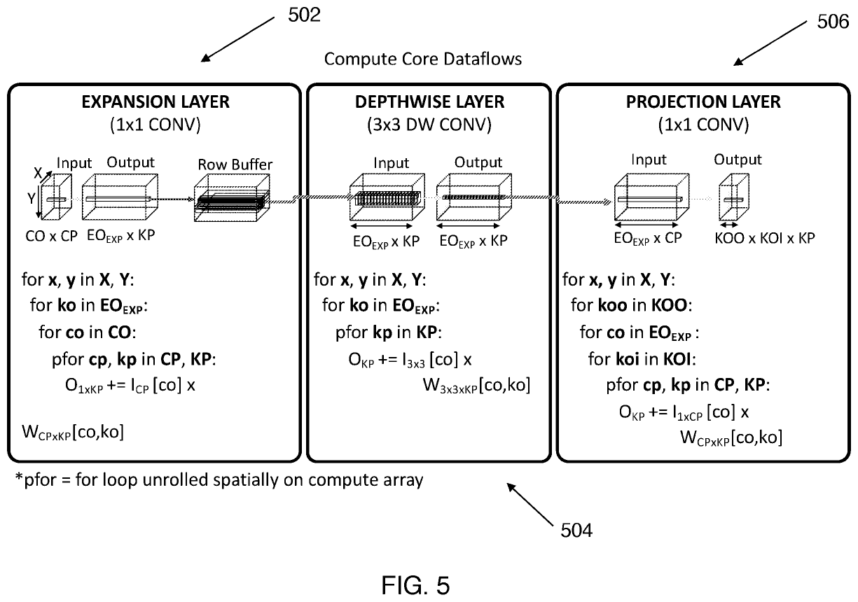

Medusa stores entire tinyML networks within its integrated ILMs, nearly eliminating the cost of accessing model parameters during continuous inference. There are dedicated cores for each of the three bottleneck sublayers (FIG. 2) to enable pixel streamed processing (FIGS. 3-4), where each input pixel is accessed only once from the Activation Memory and re-accessed from a cheap Input Single Pixel Buffer (SPB).

Bottleneck layers are used heavily in tinyML, but they are challenging to deploy on conventional accelerators due to the memory overhead of expanded activations and poor utilization for the DW layer. Here FIG. 2 schematically shows the Bottleneck layers of this example: expansion layer 202, depth-wise layer 204 and projection layer 206.

Conventional architectures suffer large amounts of data movement for bottleneck layers due to expanded feature maps. In the architecture of this example, each of the three layers 202, 204, 206 has a corresponding hardware processing core, as schematically shown on FIG. 3. Here 302 is the expansion core, 304 is the depth-wise core, and 306 is the projection core. The resulting pixel streaming capability can reduce activation memory accesses (peak memory) by 7.7× (4.8×).

In each core, the next output pixel is fully computed before moving on to the next input pixel. The Row Buffers store two rows of the expansion layer's output activation, allowing incoming pixels to complete the 3×3 input pixel patch required for computing the next DW output pixel. The Accumulation SPB enables the projection core to loop through its output channel tiles while waiting for data from earlier stages in the pipeline, improving inference latency by up to 1.75×. For a 90.3%-CIFAR-10 network benchmarked in this work, Medusa's PPS architecture with ILMs reduces memory access energy by 9.5× compared to a single-core system, which must access each of the expanded activations from Main Memory. PPS also reduces the number of Main Memory activation accesses by 7.7× and the peak activation memory by 4.8×.

FIG. 4 shows several block diagrams relating to this example. Here 402 is the multicore ML system, 404 is a detailed view of one of the three cores, 406 is a processing element of the cores, showing inclusion of the custom latch arrays as described above, and 408 shows a single pixel buffer. Medusa's PPS architecture avoids expensive re-accesses of input pixels. The low read energy of ILMs nearly eliminates the energy cost of re-accessing weights.

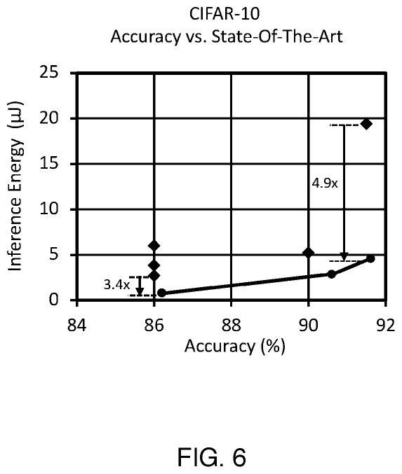

FIG. 5 shows data flows in the compute cores for this example. Here 502 is the data flow for the expansion core, 504 is the data flow for the depth-wise core, and 506 is the data core for the projection layer. The most important point here is that weights (W) are accessed in the innermost loops, relying on the low access energy needed to retrieve them from the custom latch arrays. Conventional machine learning dataflows often have the weights accessed in the outermost loop because of the energy cost to access them from main memory. By rearranging the data flow this way, per-pixel pipelining of the computation is enabled. Since the weights don't need to be in the outermost loop, the pixels can be the outermost loop, which enables per-pixel pipelining.

### Measurement Results

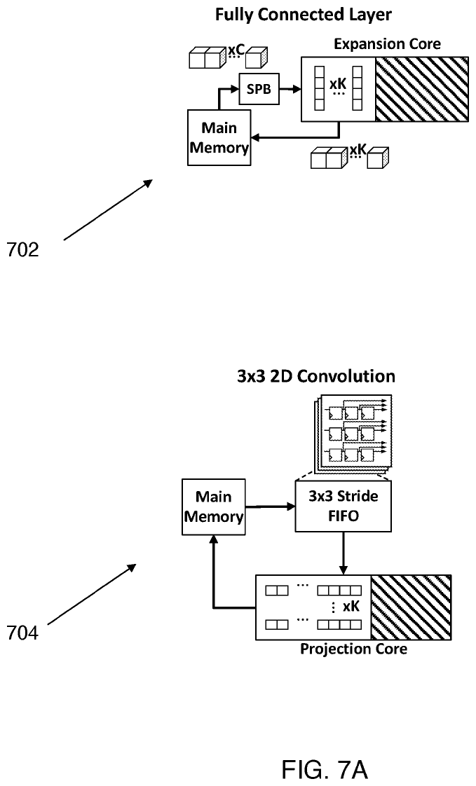

FIG. 6 shows energy-accuracy tradeoffs and a comparison with state-of-the-art. The 4.86 mm² prototype is fabricated in a 28 nm CMOS process and uses voltage-frequency (V-F) scaling to trade off inference latency and energy. It supports DNNs across a range of accuracy targets and tasks on the MLPerf Tiny Inference Benchmark, with a measured performance of 0.23-2.0 μJ at 0.27-1.0 ms and 90.8-95.5% on KWS (key word spotting), 5.0-14.7 μJ at 3.8-11.7 ms and 81.5-84.3% on VWW (visual wake words), and 0.83-4.6 μJ at 0.6-2.6 ms and 86.2-91.6% on CIFAR-10 (CIFAR is short for Canadian Institute for Advanced Research), with an achievable 4× reduction in latency via voltage scaling at only a 15% higher energy. All parameters and activations are accessed from on-chip during inference. Memory accesses make up only 20% of the total system energy owing to the PPS architecture. Medusa demonstrates a 3.4× lower inference energy (3× iso-latency) than prior art at 86% accuracy (FIG. 6). It also achieves 4. 9×/1.8× lower energy at 91.6%/90.0%.

### Programmability Features

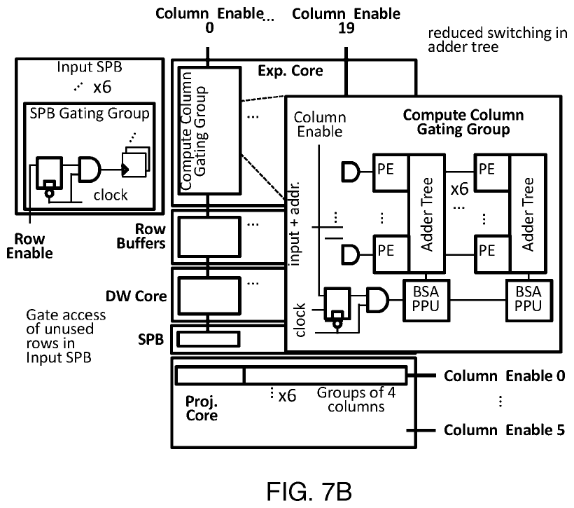

Through its configurable column gating and pipeline bypass scheme, Medusa can minimize switching in unused regions to efficiently support a range of layer types and sizes. FIGS. 7A-B show operation modes for non-bottleneck layers through pipeline bypass scheme (7A) and column gating scheme (7B). For example, 3×3 convolutions can be unrolled across the projection core, and outputs of the expansion core can be written directly to Main Memory for fully connected layers, allowing both layers to run on a single core (FIG. 7A). Within each core, Compute Columns are organized into groups with gated clock, data, and address signals (FIG. 7B).

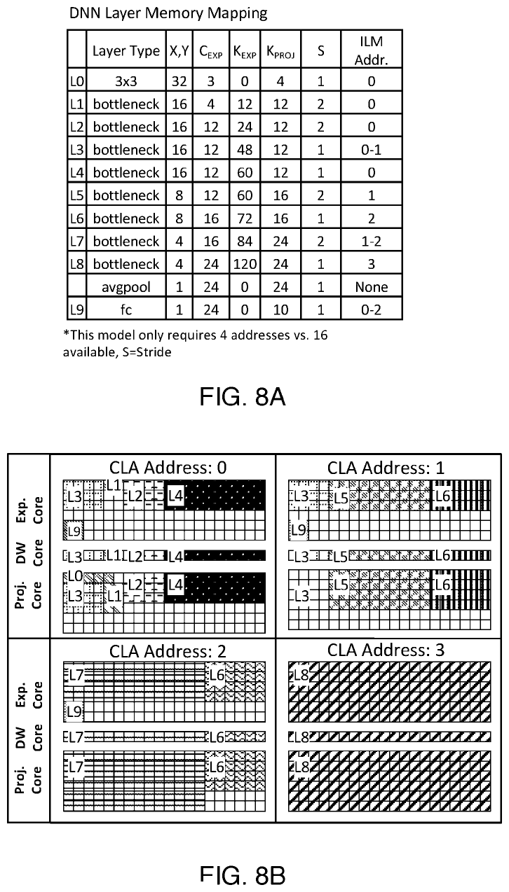

FIGS. 8A-B show a layer mapping example for a 9-layer CNN (convolutional neural network). Parameters are distributed across the array (FIG. 8A). During inference time regions of each core with the current layer weights are enabled. Layer weights are mapped across the ILMs (FIG. 8B), with unused groups gated per-layer during execution.

### Conclusion

Medusa's optimizations across DNN design, hardware architecture, and circuit design enable low-energy always-on ML inference on IoT devices.

1. A custom latch array comprising:
a 2-D array of static random-address memory cells addressed by bit-lines and word-lines; and
readout circuitry having a regeneration function and configured for direct readout without sense amplification.

2. The custom latch array of claim 1, wherein readout operations of the custom latch array are configured to be performed without prior pre-charging of the bit-lines.

3. The custom latch array of claim 1, wherein each bit line is connected to 8 or less of the static random-address memory cells.

4. An integrated circuit including the custom latch array of claim 1, wherein the custom latch array directly drives digital logic without pre-charging circuitry and without sense amplification, and wherein a read-access energy is 15 fJ/byte or less.

5. A 2-D compute core for matrix-matrix and matrix-vector multiplications comprising one or more custom latch arrays of claim 1, wherein the custom latch arrays store parameters of one or more tensors, and at each cycle different word-lines can be selected to change multiplier inputs.

6. A machine learning system comprising two or more 2-D compute cores of claim 5, wherein each 2-D core simultaneously executes a sublayer of a machine learning network in parallel, serially or pipelined.

7. The machine learning system of claim 6, wherein input/output vectors are read/written from/to a main memory once without intermediate memory buffers, and wherein a dataflow computes each output vector over multiple consecutive clock cycles, while looping through several addresses of the custom latch array.

8. The machine learning system of claim 6 wherein the two or more compute cores include an expansion core configured to perform 2-D convolution, a depth-wise core configured to perform depth-wise convolution and a projection core configured to perform 2-D convolution, and wherein the machine learning system is configured to accelerate execution of Inverted Residual and Linear Bottleneck layers of a machine learning model.

9. The machine learning system of claim 7, wherein the machine learning system is configured for image processing, and wherein each output pixel is fully computed before moving on to the next input pixel.

10. The machine learning system of claim 9, wherein an energy per inference is less than 1 μJ at an accuracy of 86% on the Cifar-10 dataset and less than 5 μJ at an accuracy of 91.6% on the Cifar-10 dataset.

11. The machine learning system of claim 9, wherein an operating point on an inference energy vs. accuracy design tradeoff curve can be determined during the machine learning training phase by varying the number of parameters.
